(19) United States
(12) Patent Application Publication
(10) Pub. No.: US 2006/0260645 A1
(43) Pub. Date: Nov. 23, 2006

(54) Methods and apparatus for processing wafers

(76) Inventors: Nicholas John Appleyard, Bristol (GB); Kevin Powell, Bristol (GB); David Andrew Tossell, Bristol (GB)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/359,264

(22) Filed: Feb. 21, 2006

Related U.S. Application Data
(60) Provisional application No. 60/654,509, filed on Feb. 22, 2005.

(51) Int. Cl. B08B 6/00; C23G 1/00; B08B 7/04; B08B 5/04; H01L 21/306

(52) U.S. Cl. 134/2; 134/21; 134/18; 134/1.3; 156/345.24

(57) ABSTRACT

A method of processing wafers or batches of wafers sequentially in a vacuum chamber (10). The method involves removing a wafer (25) from a location on a support (11); chemically cleaning particles from the support to form volatile components; and placing the subsequent wafer on the cleaned support. The method is performed without a vacuum break.

### CROSS REFERENCE TO RELATED APPLICATIONS

This application claims priority to, and the benefit of, U.S. Provisional Patent Application Ser. No. 60/654,509, filed Feb. 22, 2006, titled “Methods and Apparatus for Processing Wafers,” the entire disclosure of which is hereby incorporated by reference in its entirety.

### FIELD OF THE INVENTION

This invention relates to a method and apparatus for processing wafers or batches of wafers sequentially in a vacuum chamber.

### BACKGROUND OF THE INVENTION

Particularly in the formation of MEMS it is becoming common for wafers to be processed on both sides including features to be etched through the full thickness of a wafer and to be significantly thinned, with the result that flakes or fragments of the wafer are more likely to become deposited on the upper surface of a wafer support. This causes problems when one tries to place the next wafer at the location, particularly, as is very common, if the wafers are clamped.

Problems include: wafer mishandling possibly leading to mechanical breakage and/or poor thermal contact between the water and the support leading to process problems such as resist damage. Currently it tends to be that such incidents cause a subsequent wafer to be mishandled or are discovered on the inspection of the next wafer processed and then the processing chamber has to be opened up, necessitating a time consuming vacuum break, to allow cleaning to take place.

It is also known from U.S. Pat. No. 6,256,186 to run a short (e.g. 5 sec) etch between wafers to remove polymer film material, which has become deposited on the platen during processing. This material will always be outside the wafer location and can only cause problems if a wafer is misplaced such that it is not entirely at the wafer location on the platen.

### SUMMARY OF THE INVENTION

According to one aspect the invention comprises a method of processing wafers or batches of wafers sequentially in a vacuum chamber including:
removing a wafer from a location on the support;
chemically cleaning particles from the support to form volatile components; and
placing the subsequent wafer on the cleaned support;
the method being performed without a vacuum break.

The particles may be cleaned from the location.

According to a further aspect invention comprises a method of removing particles from a wafer location on a wafer support including performing a chemical cleaning process on the location in the absence of a wafer from the location.

In either aspect the method may further include detecting the presence of particles. For example the detection step may utilise visual recognition apparatus, in which case conveniently the surface of the support at the location may be of a colour contrast visually from the colour of the particles. The cleaning step may be performed in response to the detection of at least one particle and/or the cleaning step may be ended in response to the detection of the absence of particles from the location.

In any of these cases the particles may have a dimension in the range of 100 μm to 5 mm and in particular 0.5 mm to 2 mm

The method may include the step of assuming the particles are of the same material as the wafer and selecting a cleaning chemistry accordingly.

In any case the platen may be biased during the cleaning step to induce ion bombardment and additionally or alternatively the chemical cleaning step may be plasma assisted. In that case, where there is ion bombardment, the same power source may be used for inducing bias and the plasma.

For silicon wafers, XeF₂, ClF₃ or SF₆ gas may be utilised for the chemical cleaning step with applied plasma if required, which may be regarded as an etch process.

For aluminium or III/V semiconductors, Cl₂ and/or BCL₃ would be suitable. For organics, an oxidizing plasma e.g. O₂/CF₄ mix would be suitable. In general a gas or gas mix—with applied plasma power as appropriate should be chosen by reference to the particulate material to be removed. Where particles are of more than one predominate material type then gas mixes or sequential processes may be selected as appropriate.

In the case of at least SF₆ the chamber pressure may be at least about 30 mTorr for the cleaning step. Preferably the chamber pressure is in the range of about 30 mTorr to 80 mTorr and applied plasma power is required. For chemically active gases such as XeF₂ and ClF₃ no plasma power is required and a pressure of 5-50 Torr is appropriate.

The cleaning step may take between about 1 minute and about 15 minutes and preferably is between about 5 minutes and about 7.5 minutes. Where there is no detection system, the cleaning step may take place between every wafer or batch of wafers or it may take place after a predetermined number of wafers being processed. However, as the dropping of particles from the wafer is a generally unpredictable event it is preferred that there is either a detection system or the operator makes an inspection between each wafer.

The method may include clamping each wafer to the support for processing in which case a support may include an electrostatic chuck.

It will be appreciated that by using chemical means to remove the particles, they can essentially be converted into volatile components that can be pumped out of the chamber without the need for a vacuum break.

From a further aspect there is provided apparatus for cleaning particles from a substrate support including a vacuum chamber containing a support defining a substrate location;
a detection system for detecting particles on the substrate support at the substrate location; and
chemical cleaning apparatus for cleaning the support without a vacuum break in response to the detection of particles.

Although the invention has been defined above it is to be understood that it includes any inventive combination of the features set out above or in the following description.

### BRIEF DESCRIPTION OF THE FIGURES

The invention may be performed in various ways as specific embodiments will now be described, by way of example, with reference to the accompanying drawings, in which:

FIG. 1 is a schematic view of an “RIE” type apparatus for performing one embodiment of the invention; and

FIG. 2 is a graph correlating the initial surface area of test particles and their etch rate.

### DETAILED DESCRIPTION OF THE INVENTION

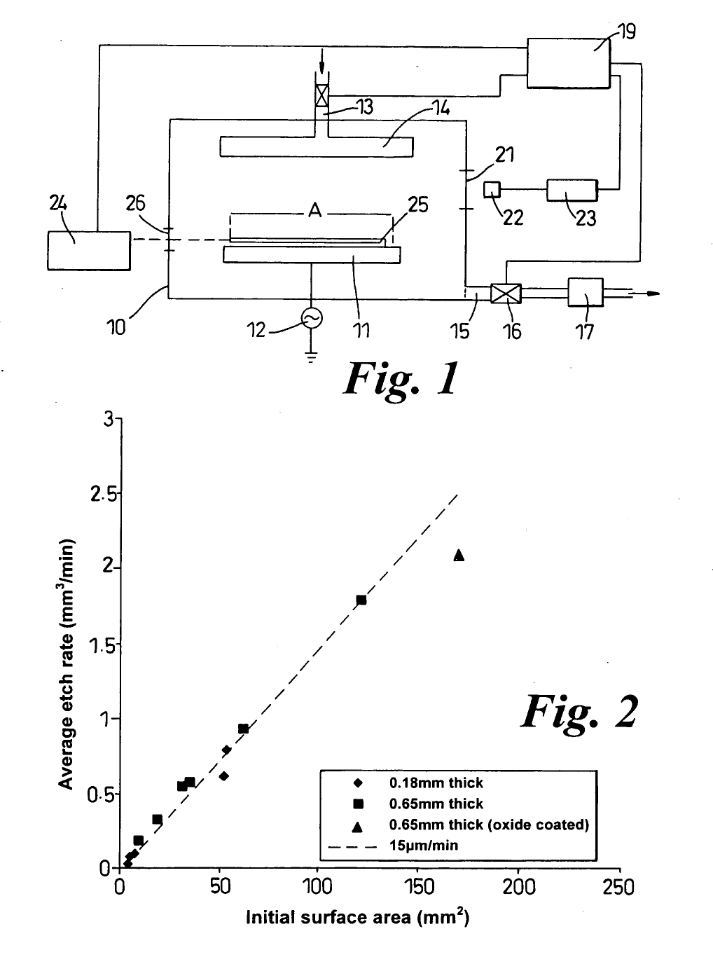

Referring to FIG. 1, a vacuum chamber 10 contains a wafer support 11, having a wafer location A and being driven by an RF supply 12, and a gas inlet 13 communicating with a shower head 14 for process gas. The chamber 10 also has an outlet 15, controlled by valve 16, to enable a pump 17 to evacuate it and to take away volatile gases. The gas inlet supply is controlled by a valve 18 and the apparatus includes a controller 19 which controls valve 16 and 18 and pump 17 in response to a visual recognition system 20, which can observe the wafer location A through a window 21 by means of a sensor 22 and a suitable computing facility at 23. A wafer handling device is schematically indicated at 24 for introducing and removing wafers 25 from the location A through a gate 26.

As will be indicated in more detail below the controller 19 also controls the wafer handling apparatus 24 and is responsive to the visual recognition system 20.

In one embodiment, this system comprises a window in the wall or ceiling of the chamber with an optical imaging apparatus that monitors the state of the support surface. This optical imaging apparatus may comprise a camera, a source of illumination and a control system with pattern recognition capability. The source of illumination may comprise an external light source, or it may comprise a plasma, initiated by applying power from a source to a suitable gas in the process chamber. In this latter embodiment, the action of illumination may be combined with an action of cleaning of the chamber or an action of declamping of a wafer.

In a second embodiment, the presence of fragments on the support may be inferred by detecting the absence of these fragments from the processed wafer, for example by comparing an image of the processed wafer to a reference image.

The subsystem that detects the presence of fragments on the support may also be used to determine the endpoint of the fragment removal process, or a separate endpoint system may be used to determine the completion of the fragment removal operation, or the processs may be operated for a predetermined length of time, according to the size or number of fragments to be removed.

In one embodiment, the subsystem that detects or infers the presence of fragments on the support may make a record of this fact for future analysis.

TABLE 1
Dimensions and disappearance times of silicon fragments
removed using a SF₆ plasma etch.

| | | Initial | | |
|---|---|---|---|---|
| | L × W × H | mass | Initial surface | Disappearance |
| Sample # | (mm) | (mg) | area (mm²) | time (s) |
| 1 | 6.0 × 4.0 × 0.18 | 10.2 | 51.6 | 330 |
| 2 | 15.0 × 1.5 × 0.18 | 9.6 | 51.0 | 400 |
| 3 | 2.5 × 1.1 × 0.18 | 1.2 | 6.8 | 310 |
| 4 | 2.5 × 0.5 × 0.19 | 0.6 | 3.6 | 435 |
| 5 | 2.0 × 0.8 × 0.19 | 0.7 | 4.2 | 220 |
| 6* | 13.5 × 5.2 × 0.65 | 107.1 | 164.9 | 1340 |
| 7 | 9.0 × 5.5 × 0.65 | 74.6 | 117.8 | 1085 |
| 8 | 6.0 × 3.9 × 0.65 | 35.7 | 59.7 | 990 |
| 9 | 3.5 × 3.0 × 0.66 | 16.1 | 29.6 | 757 |
| 10 | 7.0 × 1.6 × 0.65 | 16.9 | 33.5 | 762 |
| 11 | 5.0 × 1.0 × 0.65 | 7.6 | 17.8 | 610 |
| 12 | 1.6 × 1.6 × 0.62 | 3.7 | 9.1 | 522 |

*Sample coated with oxide on one face

### EXAMPLE

The Applicants have demonstrated the effectiveness of this method in removing silicon fragments.

Fragments with maximum dimensions ranging from 2 mm to 1 5 mm and masses from 0.5 mg to 100 mg were placed on the support, using an oxide-coated wafer as a carrier. This carrier is resistant to the etching action, and was used for convenience in the study. It does not form part of the invention.

The fragments were then exposed to a plasma formed from SF₆ gas, with additional power applied to the support in accordance with a first embodiment of the invention. The time taken for these fragments to disappear are recorded in Table 1. The plot in FIG. 2 shows that these disappearance times are correlated with the exposed surface area of the fragment, and can be interpreted with a constant etch rate of approximately 15 μm/min acting at all surfaces.

The presence of an oxide coating on one surface of one of the fragments did not significantly inhibit the removal operation.

The chamber used in this study was a specialised deep silicon etch tool which had a helicon type plasma source above the wafer, but it will be appreciated that the invention can be applied in any chamber capable of supporting an etching environment. For example Reactive Ion Etch (RIE), Inductively Coupled Plasma (ICP), diode, triode, microwave, remote and in fact any plasma source/chamber configuration suitable for etching wafers or layers upon a wafer. Similarly, although this study was restricted to removal of silicon fragments using a plasma formed from SF₆ gas, it will be appreciated that appropriate changes to the etching environment will allow fragments or particles of many other materials to be removed by the methods encompassed in this invention.

Where SF₆ is used as a process gas the following conditions have been used:
500 sccm SF₆—(a lower flow rate may be acceptable)
60 to 80 mTorr chamber pressure—(a pressure of >30 mTorr is probably acceptable).
3 kW RF source—(lower powers may be acceptable).
75 W bias (200 mm) and 30 W for a 150 mm diameter wafer were used.

The foregoing descriptions of specific embodiments of the present invention have been presented for the purpose of illustration and description. They are not intended to be exhaustive or to limit the invention to the precise forms disclosed, and obviously many modifications, embodiments, and variations are possible in lights of the above teaching. It is intended that the scope of the invention be defined by the Claims appended hereto and their equivalents.

We Claim:

1. A method of processing wafers or batches of wafers sequentially in a vacuum chamber comprising the steps of:
removing a wafer from a location on a support;
chemically cleaning particles from the support to form volatile components; and
placing the subsequent wafer on the cleaned support;
the method being performed without a vacuum break

2. A method as claimed in claim 1 wherein the particles are cleaned from the location.

3. A method of removing particles from a wafer location on a wafer support comprising performing a chemical cleaning process on the location in the absence of a wafer from the location.

4. A method as claimed in claim 1 or 3 including detecting the presence of particles.

5. A method as claimed in claim 3 wherein the detection step utilises visual recognition apparatus.

6. A method as claimed in claim 5 wherein the surface of the support at the location is of a colour which contrast visually from the colour of the particles.

7. A method as claimed in claim 4 wherein the cleaning step is performed in response to the detection of at least one particle.

8. A method as claimed in claim 4 wherein the cleaning step is ended in response to the detection of the absence of particles from the location.

9. A method as claimed in claim 1 or 3 wherein the particles have a dimension in the range of 100 micrometers to 5 millimeters.

10. A method as claimed in claim 1 or 3 including assuming the particles are of the same material as the wafer and selecting a cleaning chemistry accordingly.

11. A method as claimed in claim 1 or 3 wherein the platen is biased during the cleaning step to induce ion bombardment.

12. A method as claimed in claim 1 or 3 wherein the chemical cleaning step is plasma assisted.

13. A method as claimed in claim 1 or 3 wherein SF₆ gas is utilised for the chemical cleaning step.

14. A method as claimed in claim 13 wherein the gas is SF₆ the chamber pressure is at least about 30 mTorr for the cleaning step.

15. A method as claimed in claim 14 wherein the chamber pressure is in the range of about 30 mTorr to about 80 mTorr.

16. A method as claimed in claim 1 or 3 wherein ClF₃ or XeF₂ are utilised for the chemical cleaning step.

17. A method as claimed in claim 1 or 3 wherein the cleaning step takes between about 1 min and about 15 mins.

18. A method as claimed in claim 16 wherein the cleaning step is between about 5 mins and about 7.5 mins.

19. A method as claimed in claim 1 or 3 wherein each wafer is clamped to the support for processing.

20. A method as claimed in claim 18 wherein the support includes an electrostatic chuck.

21. Apparatus for cleaning particles from a substrate support including a vacuum chamber containing a support defining a substrate location;
a detection system for detecting particles on the substrate support at the substrate location; and
chemical cleaning apparatus for cleaning the support without a vacuum break in response to the detection of particles.
